(19) United States
(12) Patent Application Publication
(10) Pub. No.: US 2012/0098026 A1
(43) Pub. Date: Apr. 26, 2012

(54) Organic Light Emitting Diode Display and Method for Manufacturing Organic Light Emitting Diode Display

(75) Inventors: Jin-Ho Kwack, Yongin-City (KR); Dong-Won Han, Yongin-City (KR); Seung-Yong Song, Yongin-City (KR); Hyo-Jin Kim, Yongin-City (KR)

(73) Assignee: SAMSUNG MOBILE DISPLAY CO., LTD., Yongin-City (KR)

(21) Appl. No.: 13/239,597

(22) Filed: Sep. 22, 2011

(30) Foreign Application Priority Data
Oct. 25, 2010 (KR) 10-2010-0104037

(51) Int. Cl. H01L 51/52; H01L 51/56

(52) U.S. Cl. 257/100; 438/28; 257/E51.018; 257/E51.001; 257/40

(57) ABSTRACT

An organic light emitting diode (OLED) display comprises: a substrate; an organic light emitting element positioned on the substrate; an organic layer covering the organic light emitting element; and an inorganic layer including an outer portion in contact with the substrate and covering the organic layer, and an end positioned on the same line as an end of the substrate.

### CLAIM OF PRIORITY

This application makes reference to, incorporates the same herein, and claims all benefits accruing under 35 U.S.C. §119 from an application earlier filed in the Korean Intellectual Property Office on Oct. 25, 2010 and there duly assigned Serial No. 10-2010-0104037.

### BACKGROUND OF THE INVENTION

1. Field of the Invention

The present invention relates generally to an organic light emitting diode (OLED) display, and a manufacturing method of an organic light emitting diode (OLED) display. More particularly, the present invention relates to an organic light emitting diode (OLED) display using a thin film as a sealing member, and a manufacturing method of an organic light emitting diode (OLED) display.

2. Description of the Related Art

A display device is a device for displaying images and, recently, an organic light emitting diode (OLED) display has received much attention.

The OLED display has self-emission characteristics, so that, unlike a liquid crystal display (LCD), the OLED display can be formed so as to be thinner and lighter without the necessity of a light source. In addition, the OLED has high quality characteristics such as low power consumption, high luminance, and a high response speed.

Generally, the organic light emitting diode (OLED) display includes a substrate, an organic light emitting element (organic light emitting diode) positioned on the substrate, and a sealing member facing the substrate via the organic light emitting element and sealing the organic light emitting element.

Recently, an organic light emitting diode (OLED) display using a thin film as the sealing member has been developed.

The above information disclosed in this Background section is only for enhancement of an understanding of the background of the described technology, and therefore it may contain information which does not form the prior art which is already known in this country to a person of ordinary skill in the art.

### SUMMARY OF THE INVENTION

An exemplary embodiment of the invention comprises an organic light emitting diode (OLED) display capable of reducing manufacturing time and manufacturing cost, and a manufacturing method of an organic light emitting diode (OLED) display.

A first aspect of the present invention provides an organic light emitting diode (OLED) display comprising: a substrate; an organic light emitting element positioned on the substrate; an organic layer covering the organic light emitting element; and an inorganic layer including an outer portion, in contact with the substrate and covering the organic layer, and including an end positioned on an same line as the end of the substrate.

The inorganic layer may include a plurality of sub-layers made of different inorganic materials.

An angle of a cross-section of the substrate corresponding to the end of the substrate may be the same as an angle of the cross-section of the inorganic layer corresponding to the end of the inorganic layer.

A second aspect of the present invention provides a manufacturing method of an organic light emitting diode (OLED) display, comprising the steps of: forming a plurality of organic light emitting elements which are separated from each other on a mother substrate; forming a plurality of organic layers which are separated from each other and which respectively cover the plurality of organic light emitting elements on the mother substrate; forming a mother inorganic layer in contact with the mother substrate and positioned between the neighboring organic layers among the plurality of organic layers so as to continuously cover the neighboring organic layers on the mother substrate; and cutting the mother substrate and the mother inorganic layer which are positioned between the neighboring organic layers such that the end of the inorganic layer cut from the mother inorganic layer is positioned on the same line as the end of the substrate cut from the mother substrate.

The cutting of the mother substrate and the mother inorganic layer may be executed through a single cutting process.

The forming of the mother inorganic layer may include forming a plurality of sub-layers made of different inorganic materials.

According to an exemplary embodiment, an organic light emitting diode (OLED) display, and a manufacturing method of an organic light emitting diode (OLED) display which is capable of reducing the manufacturing time and the manufacturing cost, are provided.

### BRIEF DESCRIPTION OF THE DRAWINGS

A more complete appreciation of the invention, and many of the attendant advantages thereof, will be readily apparent as the same becomes better understood by reference to the following detailed description when considered in conjunction with the accompanying drawings, in which like reference symbols indicate the same or similar components, wherein:

FIG. 1 is a flowchart of a manufacturing method of an organic light emitting diode (OLED) display according to a first exemplary embodiment of the invention;

FIG. 2 and FIG. 3 are views for explaining a manufacturing method of an organic light emitting diode (OLED) display according to the first exemplary embodiment of the invention;

FIG. 4 is a cross-sectional view of an organic light emitting diode (OLED) display according to a second exemplary embodiment of the invention;

FIG. 5 is a layout view of a pixel of an organic light emitting diode (OLED) display according to the second exemplary embodiment of the invention;

FIG. 6 is a cross-sectional view taken along the line VI-VI of FIG. 5; and

FIG. 7 is an enlarged view of a portion A of FIG. 4.

### DETAILED DESCRIPTION OF THE INVENTION

The present invention will be described more fully hereinafter with reference to the accompanying drawings, in which exemplary embodiments of the invention are shown. As those skilled in the art will realize, the described embodiments may be modified in various different ways, all without departing from the spirit or scope of the present invention.

In order to clarify the present invention, parts which are not connected with the description will be omitted, and the same elements or equivalents are referred to by the same reference numerals throughout the specification.

Furthermore, as the size and thickness of the respective structural components shown in the drawings are arbitrarily illustrated for explanatory convenience, the present invention is not necessarily limited to those illustrated.

In the drawings, the thickness of layers, films, panels, regions, etc. are exaggerated for clarity, better understanding, and convenience of description. It will be understood that, when an element such as a layer, film, region, or panel is referred to as being “on” another element, it can be directly on the other element or intervening elements may also be present.

In addition, unless explicitly described to the contrary, the word “comprise” and variations such as “comprises” or “comprising” will be understood to imply the inclusion of stated elements but not the exclusion of any other elements. Furthermore, throughout the specification, “on” implies being positioned above or below a target element, and does not necessarily imply being positioned on the top on the basis of a gravity direction.

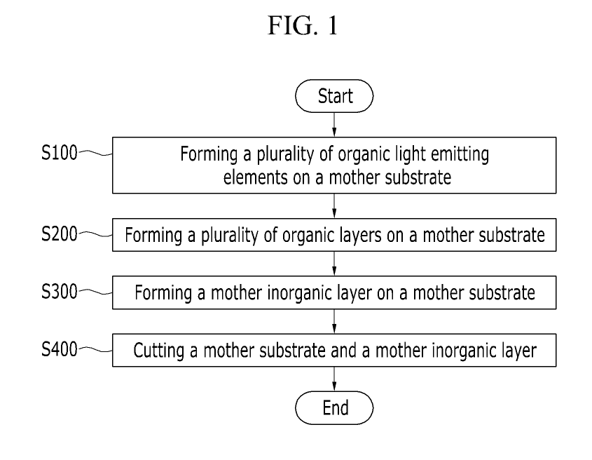

A manufacturing method of an organic light emitting diode (OLED) display according to the first exemplary embodiment will now be described with reference to FIG. 1 to FIG. 3.

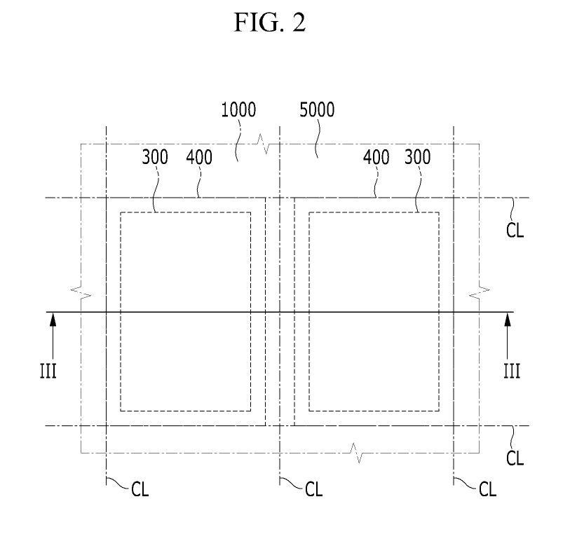

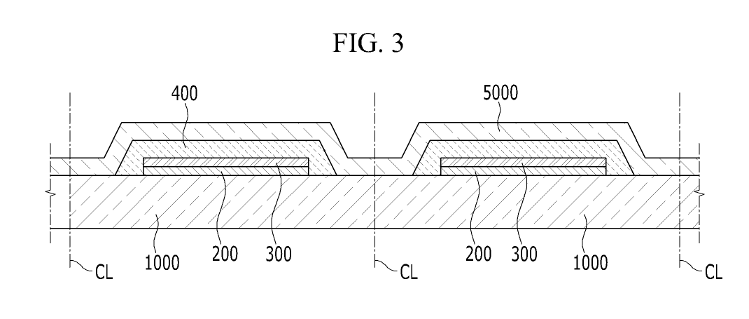

FIG. 1 is a flowchart of a manufacturing method of an organic light emitting diode (OLED) display according to a first exemplary embodiment of the invention, and FIG. 2 and FIG. 3 are views for explaining a manufacturing method of an organic light emitting diode (OLED) display according to the first exemplary embodiment of the invention. In particular, FIG. 3 is a cross-sectional view taken along the line III-III of FIG. 2.

Firstly, as shown in FIG. 1 thru FIG. 3, a plurality of organic light emitting elements 300 are formed on a mother substrate 1000 (S100 of FIG. 1).

In detail, a plurality of wire parts 200 which are separated from each other and a plurality of organic light emitting elements 300 which are separated from each other are formed on the mother substrate 1000 including glass or a resin and made of a light-transmissive material (FIG. 3). Each wire part 200 and each organic light emitting element 300 will be described through an organic light emitting diode (OLED) display according to the second exemplary embodiment.

Next, a plurality of organic layers 400 are formed on the mother substrate 1000 (S200 of FIG. 1).

In detail, a plurality of organic layers 400 respectively covering a plurality of organic light emitting elements 300 are formed by using a mask on the mother substrate 1000. The plurality of organic layers 400 are separated from each other by a mask, thereby covering each organic layer 400. Each organic layer 400 may be made of a single layer or multiple layers including a resin such as polyethylene terephthalate (PET), polyimide (PI), and polycarbonate (PC), or an engineering plastic including at least one of glass fiber reinforced plastic (FRP), polyethylene terephthalate (PET), and polymethylmethacrylate (PMMA).

Next, a mother inorganic layer 5000 is formed on the mother substrate 1000 (S300 of FIG. 1).

In detail, the mother inorganic layer 5000 is formed so as to cover the neighboring organic layer 400 or more without the usage of a mask, or by using a mask opening at the plurality of organic layers 400 which are separated from each other on the mother substrate 1000. In this case, the mother substrate 1000 positioned between the neighboring organic layers 400 is in contact with the mother inorganic layer 5000. The mother inorganic layer 5000 may be made of one layer throughout the whole mother substrate 1000 through one process. The mother inorganic layer 5000 may be made of a single layer of at least one of silicon oxide (SiOx), silicon nitride (SiNₓ), titanium oxide (TiOₓ), an aluminum oxide such as alumina (Al₂O₃), silicon oxynitride, or a plurality of sub-layers made of different inorganic materials as a deposition layer.

Next, the mother substrate 1000 and the mother inorganic layer 5000 are cut (S400 of FIG. 1).

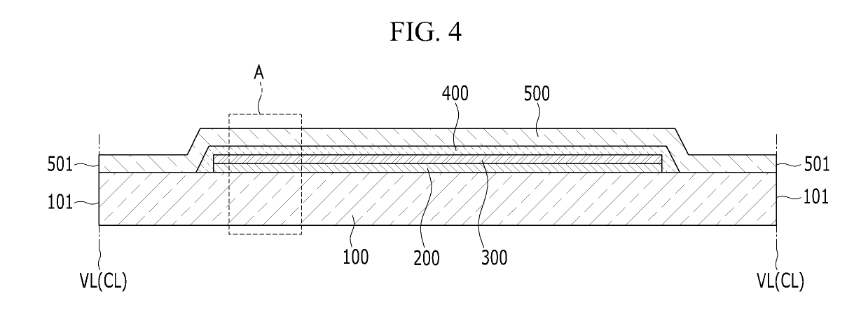

In detail, the mother substrate 1000 and the mother inorganic layer 5000 are cut in accordance with an imaginary cutting line CL positioned between the neighboring organic layer 400 by using a cutting means, such as a laser or diamond cutter, such that end portions of inorganic layers 500 (shown in FIG. 4) cut from the mother inorganic layer 5000 and end portions of the substrates 100 (shown in FIG. 4) cut from the mother substrate 1000 are positioned on the same imaginary line VL (shown in FIG. 4).

An organic light emitting diode (OLED) display according to the second exemplary embodiment, which will be described later, is manufactured by the above-described process.

As described above, in the manufacturing method of the organic light emitting diode (OLED) display according to the first exemplary embodiment, a dead space is not generated between the neighboring substrates 100 (shown in FIG. 4) manufactured from one mother substrate 1000 so that the time required to treat the dead space is eliminated, and simultaneously the waste of material is reduced. As a result, the manufacturing time and the manufacturing cost of the organic light emitting diode (OLED) display may be reduced.

Also, in the manufacturing method of the organic light emitting diode (OLED) display according to the first exemplary embodiment, the mother inorganic layer 5000 continuously covers the neighboring organic layers 400 so that the inorganic layer 500 may be formed without a mask, and thereby the manufacturing time and the manufacturing cost of the organic light emitting diode (OLED) display may be reduced.

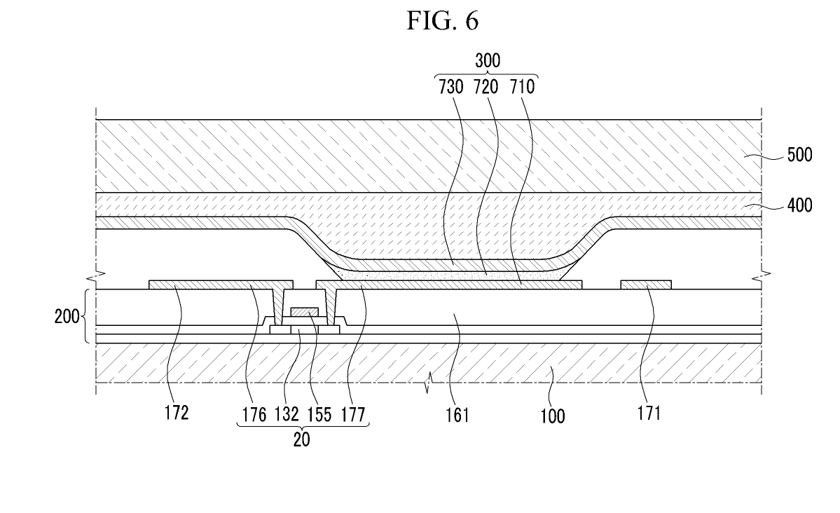

Next, an organic light emitting diode (OLED) display according to the second exemplary embodiment will be described with reference to FIG. 4 thru FIG. 6.

FIG. 4 is a cross-sectional view of an organic light emitting diode (OLED) display according to a second exemplary embodiment of the invention.

As shown in FIG. 4, an organic light emitting diode (OLED) display according to the second exemplary embodiment includes a substrate 100, a wire portion 200, an organic light emitting element 300, an organic layer 400, and an inorganic layer 500.

The substrate 100 comprises glass, and is made of a light transmissive material. The wire portion 200 and the organic light emitting element 300 are positioned on the substrate 100, and the substrate 100 faces the organic layer 400 and the inorganic layer 500, disposed with the wire portion 200 and the organic light emitting element 300 interposed therebetween. The substrate 100, the organic layer 400 and the inorganic layer 500 are sealed via the organic light emitting element 300 interposed therebetween, and the substrate 100, the organic layer 400, and the inorganic layer 500 protect the wire portion 200 and the organic light emitting element 300 from external interference. The end of the substrate 100 is positioned on an imaginary line VL. In this regard, the imaginary line VL is the cutting line CL which is described above in connection with the manufacturing method of the organic light emitting diode (OLED) display according to the first exemplary embodiment.

On the other hand, in the organic light emitting diode (OLED) display according to the second exemplary embodiment, the substrate 100 comprises glass but a substrate of an organic light emitting diode (OLED) display according to another exemplary embodiment may include a resin or metal.

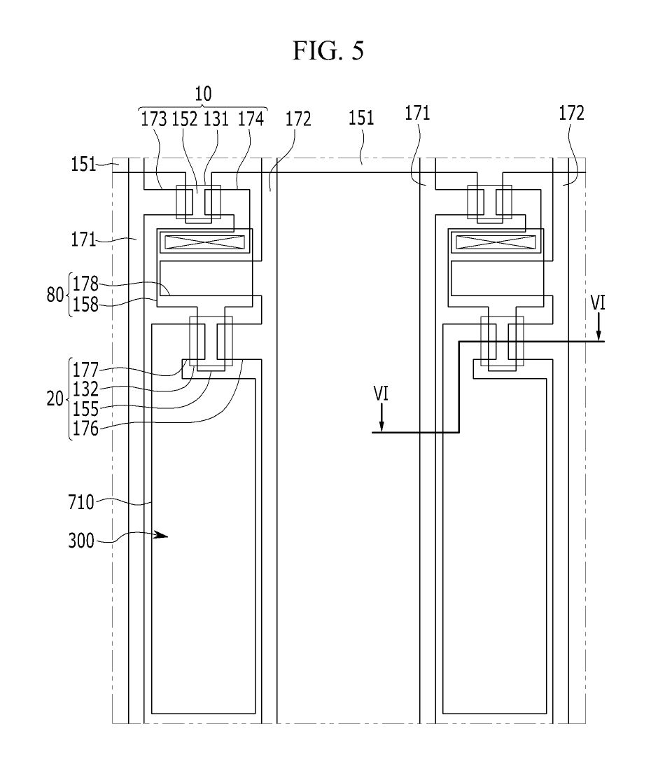

The wire portion 200 includes first and second thin film transistors 10 and 20 (shown in FIG. 5), and transmits signals to the organic light emitting element 300 so as to drive the organic light emitting element 300. The organic light emitting element 300 emits light according to the signals transmitted from the wire portion 200.

The organic light emitting element 300 is positioned on the wire portion 200.

The organic light emitting element 300 is positioned above the substrate 100, and displays images by the signals transmitted from the wire portion 200.

Next, an inner structure of an organic light emitting diode (OLED) display according to the second exemplary embodiment will be described with reference to FIG. 5 and FIG. 6.

FIG. 5 is a layout view of a pixel of an organic light emitting diode (OLED) display according to the second exemplary embodiment of the invention, and FIG. 6 is a cross-sectional view taken along the line VI-VI of FIG. 5.

Hereafter, the detailed structures of the wire portion 200 and the organic light emitting element 300 are shown in FIG. 5 and FIG. 6, but an exemplary embodiment is not limited to the structures shown in FIG. 5 and FIG. 6. The wiring part 200 and the organic light emitting diode 300 may be formed in various structures within a scope which can be easily modified by those skilled in the art. For example, in the accompanying drawings, although as the organic light emitting diode display, an active matrix (AM) type of organic light emitting diode display is shown as having a 2Tr-1 Cap structure which is provided with two thin film transistors (TFTs) and one storage capacitor in one pixel, the present invention is not limited thereto. Therefore, in the case of the organic light emitting diode display, the number of thin film transistors, the number of storage capacitors, and the number of wires are not limited. Meanwhile, the pixel represents a minimum unit for displaying an image, and the organic light emitting diode display displays the image through a plurality of pixels.

As shown in FIG. 5 and FIG. 6, the organic light emitting diode (OLED) display includes a switching thin film transistor 10, a driving thin film transistor 20, a storage capacitor 80, and an organic light emitting element 300 which are respectively formed in one pixel. Herein, a configuration including the switching thin film transistor 10, the driving thin film transistor 20, and the storage capacitor 80 is referred to as the wiring part 200. In addition, the wiring part 200 further includes a gate line 151 disposed in one direction of the substrate 100, and a data line 171 and a common power supply line 172 insulatively crossing the gate line 151. Herein, a boundary of one pixel may be defined by the gate line 151, the data line 171, and the common power supply line 172, but the invention is not limited thereto.

The organic light emitting element 300 includes a first electrode 710, an organic emission layer 720 formed on the first electrode 710, and a second electrode 730 formed on the organic emission layer 720. The first electrode 710, organic emission layer 720, and the second electrode 730 form the organic light emitting element 300. Herein, the first electrode 710 is an anode which is a hole injection electrode, and the second electrode 730 is a cathode which is an electron injection electrode. However, the exemplary embodiment is not necessarily limited thereto. Therefore, the first electrode 710 may be the cathode and the second electrode 730 may be the anode according to a driving method of the organic light emitting diode display. Holes and electrons are injected into the organic light emitting layer 720 from the first electrode 710 and the second electrode 730, respectively. When excitons generated by combining the holes and the electrons injected into the organic light emitting layer 720 fall from an excited state to a ground state, the organic emission layer 720 emits light. Also, the first electrode 710 has a light transmissive structure, and the second electrode 730 has a light reflective structure. Accordingly, the organic light emitting element 300 emits light in the direction of the substrate 100.

In the organic light emitting diode (OLED) display according to the second exemplary embodiment, the first electrode 710 has a light transmissive structure and the second electrode 730 has a light reflective structure but, in an organic light emitting diode (OLED) display according to another exemplary embodiment, one of the first electrode and the second electrode may have a light transmissive structure or a light reflective structure.

The storage capacitor 80 includes a pair of storage plates 158 and 178 which are disposed with an interlayer insulating layer 161 interposed therebetween. Herein, the interlayer insulating layer 161 becomes a dielectric, and the storage capacity of the storage capacitor 80 is determined by electric charges stored in the storage capacitor 80 and a voltage between both storage plates 158 and 178.

The switching thin film transistor 10 includes a switching semiconductor layer 131, a switching gate electrode 152, a switching source electrode 173, and a switching drain electrode 174. The driving thin film transistor 20 includes a driving semiconductor layer 132, a driving gate electrode 155, a driving source electrode 176, and a driving drain electrode 177.

The switching thin film transistor 10 is used as a switching element which selects a desired pixel to emit light. The switching gate electrode 152 is connected to the gate line 151. The switching source electrode 173 is connected to the data line 171. The switching drain electrode 174 is disposed away from the switching source electrode 173 and is connected to any one storage plate 158.

The driving thin film transistor 20 applies driving power for allowing the organic emission layer 720 of the organic light emitting diode 400 in the selected pixel to emit light toward the second electrode 730. The driving gate electrode 155 is connected to the storage plate 158, which is connected to the switching drain electrode 174. Each of the driving source electrode 176 and the other storage plate 178 is connected to the common power supply line 172. The driving drain electrode 177 is formed with the same layer as the first electrode 710, and is connected to the first electrode 710.

In the organic light emitting diode (OLED) display according to the second exemplary embodiment, the driving drain electrode 177 is positioned in the same layer as the first electrode 710 but, in the organic light emitting diode (OLED) display according to another exemplary embodiment, the driving drain electrode may be disposed in a different layer from the first electrode, and may be connected to the first electrode through an opening formed in the insulating layer.

By this structure, the switching thin film transistor 10 is operated by a gate voltage applied to the gate line 151 so as to serve to transmit a data voltage applied to the data line 171 to the driving thin film transistor 20. A voltage equivalent to a difference between the common voltage applied to the driving thin film transistor 20 from the common power supply line 172 and the data voltage transmitted from the switching thin film transistor 10 is stored in the storage capacitor 80, and current corresponding to the voltage stored in the storage capacitor 80 flows to the organic light emitting diode 300 through the driving thin film transistor 20 so as to allow the organic light emitting diode 300 to emit light.

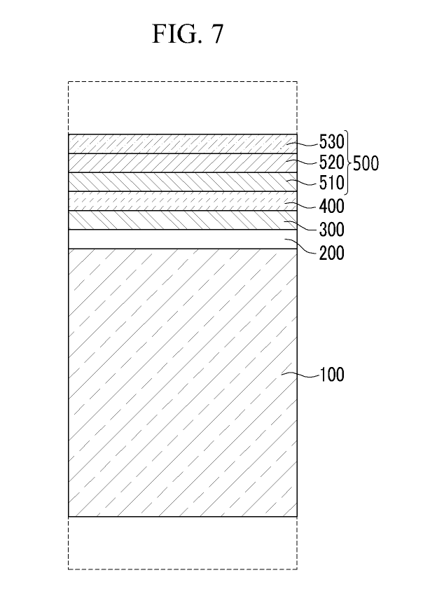

FIG. 7 is an enlarged view of a portion A of FIG. 4.

As shown in FIG. 7 and in FIG. 4, the organic layer 400 is positioned on the organic light emitting element 300. The organic layer 400 faces the substrate 100 with the organic light emitting element 300 interposed therebetween, and covers the organic light emitting element 300, thereby sealing the organic light emitting element 300. Moisture-proofing of the organic layer 400 may be decreased in comparison to the inorganic layer 500 so that the organic layer 400 is not formed on the imaginary line VL corresponding to the end of the substrate 100, and is sealed by the covering of the inorganic layer 500. The organic layer 400 has flexibility, thereby reinforcing the brittleness of the inorganic layer 500 having greater hardness than the organic layer 400, and may be a single layer or a deposition layer including a resin, such as polyethylene terephthalate (PET), polyimide (PI), and polycarbonate (PC).

On the other hand, in the organic light emitting diode (OLED) display according to the second exemplary embodiment, the organic layer 400 includes a resin including one of polyethylene terephthalate (PET), polyimide (PI), and polycarbonate (PC), and in the organic light emitting diode (OLED) display according to another exemplary embodiment, the resin layer may be a single layer or a deposition layer comprising an engineering plastic including at least one of glass fiber reinforced plastic (FRP), polyethylene terephthalate (PET), and polymethylmethacrylate (PMMA).

The center portion of the inorganic layer 500 faces the substrate 100 via the wire portion 200, the organic light emitting element 300, and the organic layer 400, and the outer portion of the organic layer 400 is in contact with the substrate 100. The inorganic layer 500 covers the organic light emitting element 300 and the organic layer 400, thereby sealing the organic light emitting element 300 and the organic layer 400. The inorganic layer 500 includes a first sub-layer 510, a second sub-layer 520 and a third sub-layer 530 which are sequentially deposited on the organic layer 400, and the first sub-layer 510, the second sub-layer 520 and the third sub-layer 530 may be a single layer or a deposition layer including one of silicon oxide (SiOx), silicon nitride (SiNₓ), titanium oxide (TiOₓ), an aluminum oxide such as alumina (Al₂O₃), and silicon oxynitride.

The end of the inorganic layer 500 is positioned on the end of the substrate 100, and in detail, the end of the inorganic layer 500 and the end of the substrate 100 are positioned on the same imaginary line VL. That is, the organic light emitting diode (OLED) display according to the second exemplary embodiment is manufactured by a manufacturing method of the organic light emitting diode (OLED) display according to the first exemplary embodiment in which the substrate 100 and the inorganic layer 500 are formed from the mother substrate 1000 and the mother inorganic layer 5000, respectively, through one cutting process so that the end of the inorganic layer 500 and the end of the substrate 100 are positioned on the same line.

Also, the organic light emitting diode (OLED) display according to the second exemplary embodiment is manufactured by the manufacturing method of the organic light emitting diode (OLED) display according to the first exemplary embodiment in which the substrate 100 and the inorganic layer 500 are formed from the mother substrate 1000 and the mother inorganic layer 5000, respectively, through one cutting process so that the angle of a substrate cross-section 101 of the substrate 100 corresponding to the end of the substrate 100 is the same as the angle of an inorganic layer cross-section 501 of the inorganic layer 500 corresponding to the inorganic layer 500.

As described above, in the organic light emitting diode (OLED) display according to the second exemplary embodiment, the organic layer 400 and the organic light emitting element 300 are completely sealed by the inorganic layer 500, the outer portion of which is in contact with the substrate 100 so that infiltration of moisture into the organic light emitting element 300 from the outside is minimized. Accordingly, the life-span of the organic light emitting diode (OLED) display may be extended.

Also, the organic light emitting diode (OLED) display of the second exemplary embodiment is manufactured through the manufacturing method of the organic light emitting diode (OLED) display according to the first exemplary embodiment in which a dead space does not exist between the neighboring substrates 100 which are manufactured from one mother substrate 1000 so that time to treat the dead space is eliminated and simultaneously wasted material is reduced, thereby reducing the manufacturing time and the manufacturing cost.

Furthermore, the organic light emitting diode (OLED) display according to the second exemplary embodiment is manufactured by the manufacturing method of the organic light emitting diode (OLED) display according to the first exemplary embodiment in which the mother inorganic layer 5000, continuously covering the organic layer 400, is formed at one time so that the inorganic layer 500 may be formed without a mask, thereby reducing the manufacturing time and the manufacturing cost.

While this disclosure has been described in connection with what is presently considered to be practical exemplary embodiments, it is to be understood that the invention is not limited to the disclosed embodiments but, on the contrary, is intended to cover various modifications and equivalent arrangements included within the spirit and scope of the appended claims.

What is claimed is:

1. An organic light emitting diode (OLED) display, comprising:
a substrate;
an organic light emitting element positioned on the substrate;
an organic layer covering the organic light emitting element; and
an inorganic layer including an outer portion in contact with the substrate and covering the organic layer, and an end positioned on a same line as an end of the substrate.

2. The organic light emitting diode (OLED) display of claim 1, wherein the inorganic layer includes a plurality of sub-layers made of different inorganic materials.

3. The organic light emitting diode (OLED) display of claim 1, wherein an angle of a cross-section of the substrate corresponding to the end of the substrate is the same as an angle of a cross-section of the inorganic layer corresponding to an end of the inorganic layer.

4. A method for manufacturing an organic light emitting diode (OLED) display, comprising the steps of:
forming a plurality of organic light emitting elements which are separated from each other on a mother substrate;
forming a plurality of organic layers which are separated from each other and respectively cover the plurality of organic light emitting elements on the mother substrate;
forming a mother inorganic layer in contact with the mother substrate positioned between neighboring organic layers among the plurality of organic layers so as to continuously cover the neighboring organic layers on the mother substrate; and
cutting the mother substrate and the mother inorganic layer which are positioned between the neighboring organic layers so that an end of the inorganic layer cut from the mother inorganic layer is positioned on a same line as an end of the substrate cut from the mother substrate.

5. The method of claim 4, wherein the cutting of the mother substrate and the cutting of the mother inorganic layer are executed through a single cutting process.

6. The method of claim 4, wherein the forming of the mother inorganic layer includes forming a plurality of sub-layers made of different inorganic materials.
